(19) United States
(12) Patent Application Publication
(10) Pub. No.: US 2026/0066222 A1
(43) Pub. Date: Mar. 5, 2026

(54) MULTIBEAM WRITING METHOD AND MULTIBEAM WRITING APPARATUS

(71) Applicant: NuFlare Technology, Inc., Yokohama-shi (JP)

(72) Inventors: Yusuke SAITO, Yokohama-shi (JP); Issei AIBARA, Yokohama-shi (JP)

(73) Assignee: NuFlare Technology, Inc., Yokohama-shi (JP)

(21) Appl. No.: 19/269,556

(22) Filed: Jul. 15, 2025

(30) Foreign Application Priority Data
Sep. 3, 2024 (JP) 2024-151669

(51) Int. Cl. H01J 37/317; G03F 7/00

(52) U.S. Cl. CPC H01J 37/3177; G03F 7/704; G03F 7/7055; H01J 37/3175

(57) ABSTRACT

In one embodiment, a multibeam writing method includes acquiring a current density distribution of multiple beams formed using a charged particle beam emitted from a charged particle source, comparing the acquired current density distribution with a preset ideal shape of the current density distribution, and performing a beam adjustment on the multiple beams in a case where a difference at a predetermined position is greater than a threshold value.

### CROSS REFERENCE TO RELATED APPLICATION

This application is based upon and claims benefit of priority from the Japanese Patent Application No. 2024-151669, filed on Sep. 3, 2024, the entire contents of which are incorporated herein by reference.

### FIELD

The present invention relates to a multibeam writing method and a multibeam writing apparatus.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. So-called electron beam lithography technique, in which resist is exposed by an electron beam writing apparatus to form patterns, is used to produce high-precision original patterns.

For example, there are writing apparatuses that use multiple beams. Compared with cases where writing is performed using a single electron beam, irradiation with more beams at once can be performed by using multiple beams, thereby significantly increasing throughput. In a multibeam writing apparatus, for example, an electron beam emitted from an electron source passes through a shaping aperture array substrate, which has multiple apertures arranged in a matrix, to form multiple beams having a rectangular beam array shape. Each of the multiple individual beams that form the multiple beams is individually controlled for blanking, the unshielded individual beams are deflected by the deflector, and the desired positions on the sample are irradiated with the deflected beams.

As the electron source of the multibeam writing apparatus, a thermionic-emission electron source with a cathode serving as a heater is used. In this electron source, electrons are emitted by heating the cathode. The emitted electrons are accelerated by the acceleration voltage and emitted as an electron beam.

The current density distribution of the electron beam emitted from the electron source changes as the cathode wears out, for example. Thus, the current density distribution within the multiple beams also changes, which may affect the pattern writing accuracy.

### BRIEF DESCRIPTION OF THE DRAWINGS

FIG. 1 is a schematic diagram of a multibeam writing apparatus according to an embodiment of the present invention.

FIG. 2 is a plan view of a shaping aperture array substrate.

FIG. 3 is a flowchart illustrating a multibeam writing method.

FIG. 4 is a flowchart illustrating a feature value calculation process.

FIG. 5 is a flowchart illustrating a beam restriction process.

FIG. 6 is a diagram illustrating an example of a measurement result of a current density distribution.

### DETAILED DESCRIPTION

In one embodiment, a multibeam writing method includes acquiring a current density distribution of multiple beams formed using a charged particle beam emitted from a charged particle source, comparing the acquired current density distribution with a preset ideal shape of the current density distribution, and performing a beam adjustment on the multiple beams in a case where a difference at a predetermined position is greater than a threshold value.

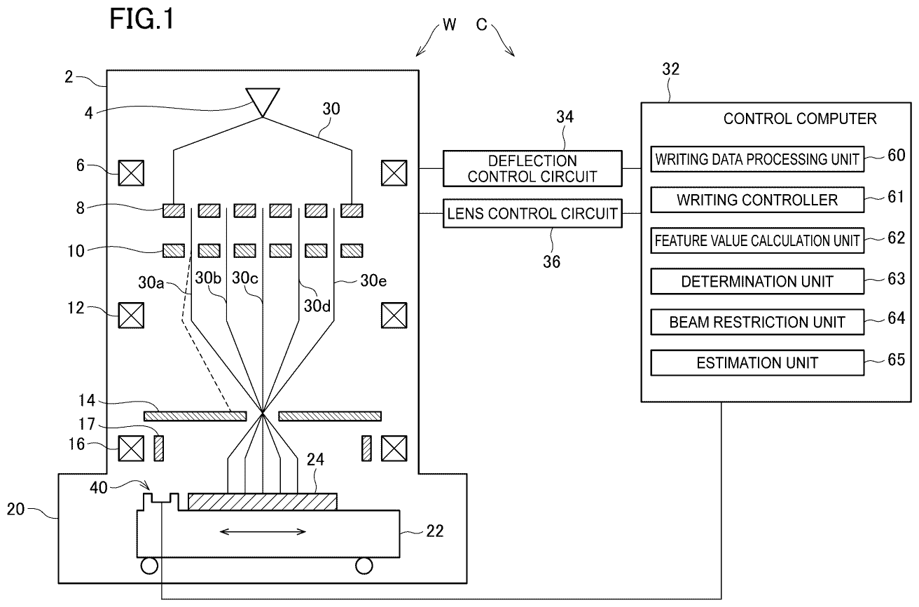

FIG. 1 is a schematic diagram of a multibeam writing apparatus according to an embodiment of the present invention. In the present embodiment, a configuration using an electron beam as an example of a charged particle beam will be described. The charged particle beam is not limited to the electron beam. For example, the charged particle beam may be an ion beam.

This writing apparatus includes a writing unit W and a control unit C. The writing unit W writes a desired pattern by irradiating a substrate 24, which is used as a writing target, with an electron beam. The control unit C controls the operation of the writing unit W.

The writing unit W includes an electron-optical column 2 and a writing chamber 20. In the electron-optical column 2, an electron source 4, an illumination lens 6, a shaping aperture array substrate 8, a blanking aperture array substrate 10, a reduction lens 12, a limiting aperture member 14, an objective lens 16, and a deflector 17, for example, are arranged.

In the writing chamber 20, an XY stage 22 is arranged. On the XY stage 22, the substrate 24 used as a writing target is placed. Examples of the substrate 24 used as a writing target include wafers and masks for exposures that transfer patterns to wafers using reduced projection exposure apparatuses such as steppers and scanners that use an excimer laser as the light source, and extreme ultraviolet (EUV) exposure apparatuses.

A current detector 40, such as a Faraday cup, is arranged on the XY stage 22 at a different position from where the substrate 24 is placed.

The control unit C has a control computer 32, a deflection control circuit 34, and a lens control circuit 36.

The control computer 32 has a writing data processing unit 60, a writing controller 61, a feature value calculation unit 62, a determination unit 63, a beam restriction unit 64, and an estimation unit 65. Each unit of the control computer 32 may be configured using hardware, such as electrical circuits, or software, such as a program that executes these functions. When each unit is configured using software, a program that realizes these functions may be stored in a recording medium and may be loaded into a computer that includes electric circuits, for example, for execution.

Writing data obtained by converting design data (layout data) into a format for writing apparatuses is stored in a storage device, which is not illustrated. The writing data processing unit 60 reads the writing data from this storage device and performs a multi-stage data conversion process to generate shot data. The shot data is generated for each pixel, and the writing time (irradiation time) is calculated. For example, in a case where no pattern is formed on a target pixel, beam irradiation is not performed for the target pixel. Thus, an identification code indicating zero writing time or no beam irradiation is defined. In this case, a maximum writing time T (maximum exposure time) in a single multibeam shot is set in advance. It is suitable if the irradiation time for each beam with which irradiation is actually to be performed is determined in proportion to the calculated area density of the pattern. It is also suitable if the finally calculated irradiation time for each beam is the time corresponding to the corrected irradiation dose, which is obtained by correcting the irradiation dose using a dimensional variation for phenomena causing dimensional variation, such as proximity effect, overshadowing effect, and loading effect. Thus, the irradiation time for each beam with which irradiation is actually to be performed can vary from beam to beam. The writing time (irradiation time) for each beam is calculated using a value within the maximum writing time T. In addition, the writing data processing unit 60 treats the calculated irradiation time data for each pixel as data for the beam that is to write the pixel, and generates, for each multibeam shot, irradiation time array data (shot data) in which the data is arranged in the array order of the individual beams of multiple beams.

The deflection control circuit 34 uses the irradiation time array data to generate deflection-amount data for deflecting the multiple beams. The writing controller 61 outputs control signals for performing a writing process to the deflection control circuit 34 and a control circuit (not illustrated) that drives the writing unit W. The writing unit W has an optical system including the deflector and lenses which control a trajectory of the multiple beams. Based on the control signal, the writing unit W writes a desired pattern on the substrate 24 using multiple beams. Specifically, the operation is performed as follows.

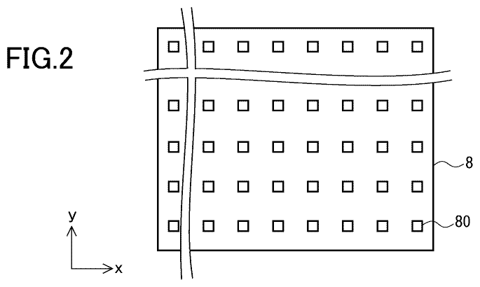

An electron beam 30 emitted from the electron source 4 is caused to illuminate the entirety of the shaping aperture array substrate 8 almost vertically by the illumination lens 6. FIG. 2 is a conceptual diagram illustrating the configuration of the shaping aperture array substrate 8. The shaping aperture array substrate 8 has a matrix of apertures 80, arranged in m columns in the vertical (y) direction and n rows in the horizontal (x) direction (m, n≥2) and formed with a predetermined array pitch. For example, the apertures 80, which are arranged in 512 columns and 512 rows, are formed. Each aperture 80 is formed, for example, in a rectangular shape with the same dimensions. Each aperture 80 may be circular with the same diameter.

The electron beam 30 illuminates a region of the shaping aperture array substrate 8 that includes all of the apertures 80. A portion of the electron beam 30 passes through each of these multiple apertures 80, resulting in the formation of multiple beams 30a to 30e, as illustrated in FIG. 1.

The blanking aperture array substrate 10 has through holes formed so as to be aligned with the arrangement position of each aperture 80 of the shaping aperture array substrate 8, and a blanker constituted by two electrodes serving as a pair is arranged at each through hole. The electron beams 30a to 30e passing through the respective through holes are deflected independently of each other by the voltages applied by the blankers. This deflection controls the blanking of each beam. The blanking aperture array substrate 10 performs blanking deflection on each beam of the multiple beams that have passed through the multiple apertures 80 of the shaping aperture array substrate 8.

Each of the multiple beams 30a to 30e that have passed through the blanking aperture array substrate 10 is reduced in beam size and array pitch by the reduction lens 12 and proceeds toward the central aperture formed in the limiting aperture member 14. Each electron beam deflected by a corresponding blanker of the blanking aperture array substrate 10 is displaced from the center aperture of the limiting aperture member 14 due to the displacement of its trajectory and is shielded by the limiting aperture member 14. In contrast, each electron beam that is not deflected by a corresponding blanker of the blanking aperture array substrate 10 passes through the center aperture of the limiting aperture member 14.

The limiting aperture member 14 shields the individual electron beams that are deflected by the corresponding blankers of the blanking aperture array substrate 10 so as to be in a beam-off state. The beams that pass through the limiting aperture member 14 from when the beams are switched on until the beams are switched off are electron beams for a single shot.

The electron beams 30a to 30e that have passed through the limiting aperture member 14 are focused by the objective lens 16 to form a pattern image with a desired reduction ratio on the substrate 24. The individual electron beams (all the multiple beams) that have passed through the limiting aperture member 14 are deflected in a collective manner in the same direction by the deflector 17. The substrate 24 is irradiated with the deflected beams.

The multiple beams with which irradiation is performed at once are ideally aligned at a pitch obtained by multiplying the array pitch of the multiple apertures 80 of the shaping aperture array substrate 8 by the desired reduction ratio described above. This writing apparatus performs a writing operation using a raster scan method, in which irradiation with shot beams is continuously performed in sequence. In a case where this writing apparatus writes a desired pattern, beams are controlled to be switched on through the blanking control in accordance with the pattern. When the XY stage 22 is moving continuously, the beam irradiation positions are controlled by the deflector 17 to follow the movement of the XY stage 22.

The electron source is a thermionic-emission electron gun with a cathode serving as a heater, and the current density distribution of the electron beam emitted from the electron source 4 changes as the cathode wears out, for example. Thus, the current density distribution of the multiple beams also changes, which can affect the writing accuracy.

In the present embodiment, the current density distribution of the multiple beams is measured. In a case where if the change is large, beam adjustment is performed to correct the current density distribution. In a case where the current density distribution cannot be sufficiently corrected even through the beam adjustment, the use of beams with reduced current densities will be restricted.

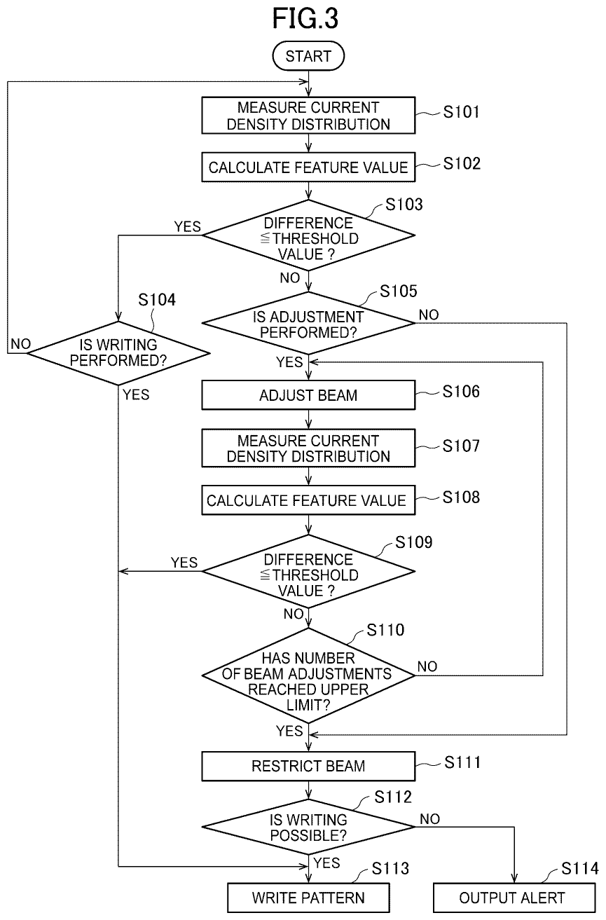

A multibeam writing method according to the present embodiment is described in accordance with the flowchart illustrated in FIG. 3.

The amount of current of each of the multiple beams is measured to acquire the current density distribution (Step S101). For example, the XY stage 22 is controlled to move the current detector 40 to the position which is irradiated with each of the multiple beams. The current detector 40 is irradiated with the individual beams one by one that constitute the multiple beams, and the amount of current of each beam is measured. The current detector 40 may be irradiated with, instead of a single beam, several neighboring beams together to measure the amount of current of the beam group.

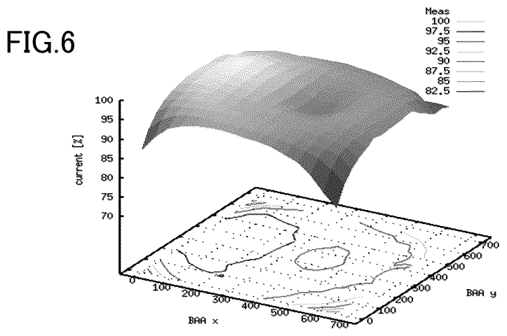

The feature value calculation unit 62 calculates the current density from the amount of current of each beam to acquire a current density distribution (Step S101). For example, the current density distribution as illustrated in FIG. 6 is obtained. In this example, the current densities at the four corners of the multiple beams having a rectangular beam array shape are lower. Moreover, there is a recessed area in the current density distribution at the center of the beam array.

The feature value calculation unit 62 calculates a feature value of the current density distribution (Step S102). The determination unit 63 determines whether or not the difference between the calculated feature value and the ideal value is less than or equal to a threshold value (Step S103). The details of the feature value calculation and threshold-value-based determination will be described below.

In a case where the difference is less than or equal to the threshold value (Step S103_Yes) and where writing is to be performed (Step S104_Yes), a pattern writing process is performed on the substrate 24 (Step S113). In a case where the timing is not for writing (Step S104_No), the process returns to Step S101. Alternatively, the process may be held in standby until the writing process begins.

In a case where the difference is greater than the threshold value (Step S103_No), it is determined whether or not a beam adjustment is to be performed (Step S105). In a case where the cathode of the electron source 4 has reached the end of its life, a beam adjustment is not performed (Step S105_No), and beam restriction is performed as described below (Step S111).

In a case where a beam adjustment is to be performed (Step S105_Yes), the lens control circuit 36 adjusts the lens values of the various lenses in the electron-optical column 2 (Step S106). For example, the lens control circuit 36 performs alignment adjustment so that the current densities at the four corners of the multibeam become higher.

After the beam adjustment, the current density distribution is measured (Step S107), a feature value is calculated (Step S108), and a threshold-value-based determination is performed (Step S109). Steps S107 to S109 are processes substantially the same as Steps S101 to S103.

In a case where the difference between the calculated feature value and the ideal value becomes less than the threshold value due to the beam adjustment (Step S109_Yes), the pattern writing process is performed on the substrate 24 (Step S113).

In a case where the number of beam adjustments has not reached a predetermined upper limit (Step S110_No), the beam adjustment, the current density distribution measurement, the feature value calculation, and the threshold-value-based determination (Steps S106 to S109) are performed again.

In a case where the number of beam adjustments has reached the predetermined upper limit (Step S110_Yes), the beam restriction unit 64 restricts the use of beams with low current densities as beams that are not used for writing (Step S111). Details of this beam restriction will be described below.

The determination unit 63 determines whether or not the writing process can be performed in a state where the use of some beams is restricted (Step S112). In a case where writing is possible (Step S112_Yes), the pattern writing process is performed on the substrate 24 (Step S113). In a case where it is determined that writing is not possible (Step S112_No), such as when a desired writing speed cannot be achieved, an alert is output (Step S114).

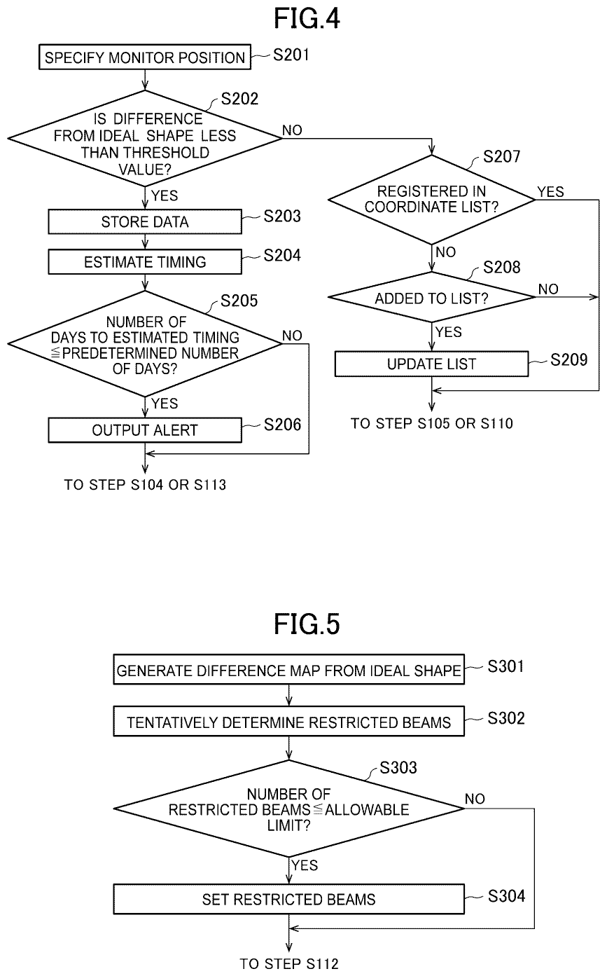

Next, the feature value calculation and threshold-value-based determination (Steps S102, S103, S108, and S109) will be described in accordance with the flowchart illustrated in FIG. 4.

The positions where the current density is to be monitored are specified within the multiple beams (Step S201). For example, the four corners of the rectangular beam array are specified. In a case where the current density distribution is measured in advance and recessed areas with lower current density, which are located other than the four corners, are known, the recessed areas are also specified. The four corners and the recessed areas are registered in the list of coordinates to be monitored. The current densities at the specified positions are calculated as feature values. In a case where the number of beams for which the beam current is measured in Steps S101 and S107 of FIG. 3 is small, data interpolation may be performed through interpolation.

Each feature value of the current density distribution is compared with the value of the current density (ideal value) at the corresponding monitor position in the ideal shape of the current density distribution, and it is determined whether or not the difference is less than or equal to the threshold value (Step S202). In this case, the ideal shape of the current density distribution may be flat, the Gaussian distribution, or the initial shape of the current density distribution after the completion of the writing apparatus adjustment. In comparing the feature values with the ideal values, a normalization process may be performed on the current density distribution.

In a case where the difference is less than or equal to the threshold value (Step S202_Yes), the measurement data of the measured current density distribution is stored in a memory (not illustrated) (Step S203).

The estimation unit 65 estimates the timing at which the differences between the feature values and the ideal values will reach the threshold value through extrapolation of the stored measurement data set (Step S204). In a case where the number of days to the estimated timing is not less than or equal to a predetermined number of days (Step S205_No), the process proceeds to Step S104 or S113 of FIG. 3. In a case where the number of days to the estimated timing is less than or equal to the predetermined number of days (Step S205_Yes), an alert is output (Step S206), and then the process proceeds to Step S104 or S113 of FIG. 3.

In a case where any of the areas where the corresponding difference is greater than the threshold value is not registered in the coordinate list (Steps S202_No and S207_No), it is determined whether or not to add the area to the list (Step S208). In a case where the area is to be added to the list, the list is updated (Step S208_Yes and S209). Thereafter, the process proceeds to Step S105 or S110 of FIG. 3.

Next, a beam restriction process (Step S111 of FIG. 3) will be described in accordance with the flowchart illustrated in FIG. 5.

The beam restriction unit 64 generates a difference map between the current density distribution generated in Step S101 or S107 and the ideal shape of the current density distribution (Step S301).

The beam restriction unit 64 refers to the difference map and tentatively determines the beams for which the difference is greater than or equal to a predetermined value to be the restricted beams (Step S302).

In a case where the number of restricted beams tentatively determined in Step S302 is less than or equal to the allowable limit (Step S303_Yes), the beam restriction unit 64 sets the restricted beams, which are tentatively determined, as use-restricted beams that remain off at all times (Step S304). The allowable limit is determined in consideration of the writing conditions and other factors. Thereafter, the process proceeds to Step S112 of FIG. 3.

In this manner, according to the present embodiment, in a case where the current density distribution of multiple beams deviates from the ideal shape, the beam adjustment is performed to bring it closer to the ideal shape. In a case where the current density distribution cannot be sufficiently improved through the beam adjustment due to factors such as the progression of cathode wear in the electron source, the use of the beams is restricted. This can suppress a decrease in pattern writing accuracy.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multibeam writing method comprising:
acquiring a current density distribution of multiple beams formed using a charged particle beam emitted from a charged particle source;
comparing the acquired current density distribution with a preset ideal shape of the current density distribution; and performing a beam adjustment on the multiple beams in a case where a difference at a predetermined position is greater than a threshold value.

2. The multibeam writing method according to claim 1, wherein the ideal shape is flat or a Gaussian distribution.

3. The multibeam writing method according to claim 1, wherein a pattern is written by irradiating a substrate with the multiple beams subjected to the beam adjustment.

4. The multibeam writing method according to claim 1, wherein the current density distribution of the multiple beams acquired after the beam adjustment is compared with the ideal shape, and a beam corresponding to the predetermined position is set as a use-restricted beam in a case where the difference at the predetermined position is greater than the threshold value, and
a pattern is written by irradiating a substrate with the multiple beams in which the beam set as the use-restricted beam is controlled to remain off at all times.

5. A multibeam writing apparatus comprising:
a charged particle source emitting a charged particle beam;
a multibeam forming unit forming multiple beams using the charged particle beam;
a current detector detecting a beam current of each of the multiple beams;
a calculation circuit calculating a current density distribution of the multiple beams using the beam currents;
a determination circuit comparing the calculated current density distribution with a preset ideal shape of the current density distribution to determine whether or not a difference at a predetermined position is greater than a threshold value;
a control circuit performing a beam adjustment on the multiple beams in a case where the difference is greater than the threshold value; and
a writing unit including a stage and an optical system which controls a trajectory of the multiple beams, and writing a pattern by irradiating a substrate on the stage with adjusted multiple beams by the beam adjustment.

6. The multibeam writing apparatus according to claim 5, wherein the control circuit includes a beam restriction circuit that sets a beam corresponding to the predetermined position as a use-restricted beam in a case where the difference at the predetermined position is greater than the threshold value as a result of a comparison between the current density distribution after the beam adjustment with the ideal shape, and
the control circuit performs control so that the beam set as the use-restricted beam remains off at all times.
